(19) United States
(12) Patent Application Publication
(10) Pub. No.: US 2013/0015986 A1
(43) Pub. Date: Jan. 17, 2013

(54) KEYBOARD WITH ADJUSTABLE KEYSTROKE DISTANCE AND ELECTRONIC DEVICE USING THE SAME

(71) Applicant: CHENG-HUANG LU, Shenzhen City (CN)

(72) Inventor: CHENG-HUANG LU, Shenzhen City (CN)

(73) Assignees: HON HAI PRECISION INDUSTRY CO., LTD., Tu-Cheng (TW); FU TAI HUA INDUSTRY (SHENZHEN) CO., LTD., ShenZhen City (CN)

(21) Appl. No.: 13/214,232

(22) Filed: Aug. 22, 2011

(30) Foreign Application Priority Data
Jul. 14, 2011 (CN) 201110197533.X

(51) Int. Cl. H03M 11/00

(52) U.S. Cl. 341/32

(57) ABSTRACT

A keyboard for use in an electronic device includes a circuit board, a switch connected to the circuit board and a button to actuate the switch. The keyboard further includes a first electromagnet and a second electromagnet. The first electromagnet is coupled to the button, and the second electromagnet is coupled to the circuit board and corresponding to the first electromagnet. When energized, the first and second electromagnets repel each other and the first electromagnet moves away from the circuit board, causing the distance between the button and the switch to become longer.

### BACKGROUND

1. Technical Field

The present disclosure relates to a keyboard and an electronic device with the keyboard, and more specifically to a keyboard having adjustable keystroke distance.

2. Description of Related Art

As common input devices, keyboards are widely used in various electronic devices, such as personal digital assistants, mobile phones, and computers. One such keyboard 1 is shown in FIG. 1, which includes a circuit board 11 and a button 12. When pushed, the button 12 actuates a switch 13 on the circuit board 11. After being actuated, the switch 13 sends a signal to a processor of the electronic device, the processor executes a corresponding operation in response. However, for a very small electronic device with a slim profile, the distance between the button 12 and the circuit board 11 necessarily becomes shorter. That is, the device requires a short travel distance for a keystroke, which does not provide very good tactile feedback to a user.

Therefore, what is needed is a keyboard to solve the problems described above.

### BRIEF DESCRIPTION OF THE DRAWINGS

FIG. 1 is a partial, isometric view of a related art keyboard.

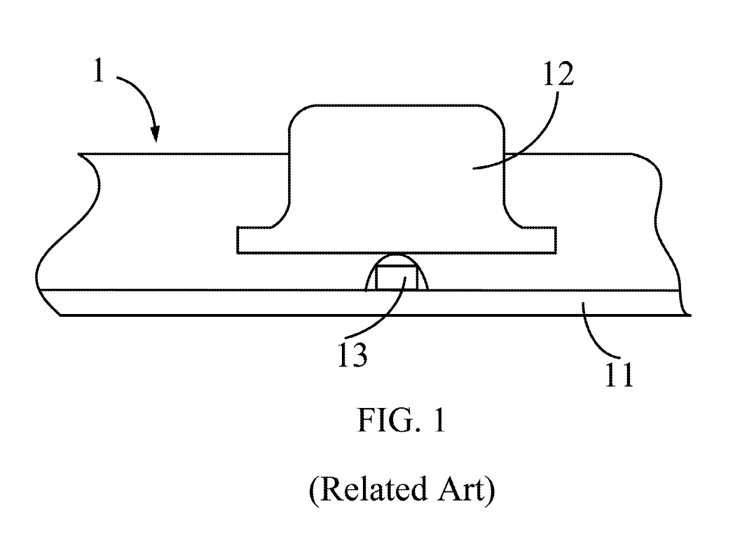

FIG. 2 is a partial, isometric view of a keyboard in a first state, in accordance with an embodiment.

FIG. 3 is similar to FIG. 2, but showing the keyboard in a second state.

FIG. 4 is a block diagram of a processor of an electronic device for use with the keyboard of FIGS. 2-3, in accordance with an embodiment.

### DETAILED DESCRIPTION

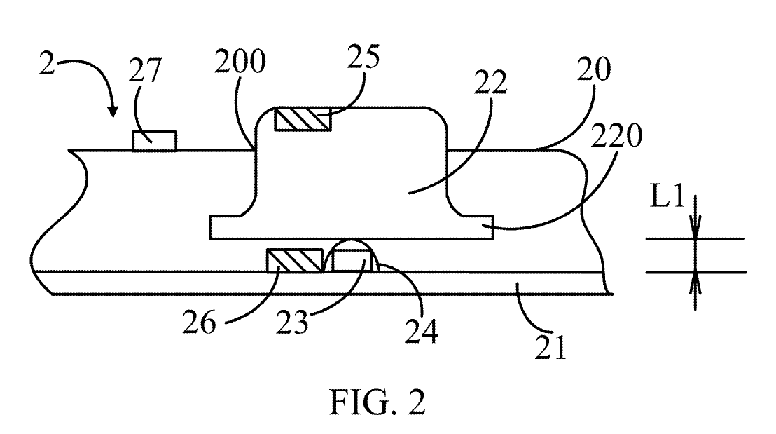

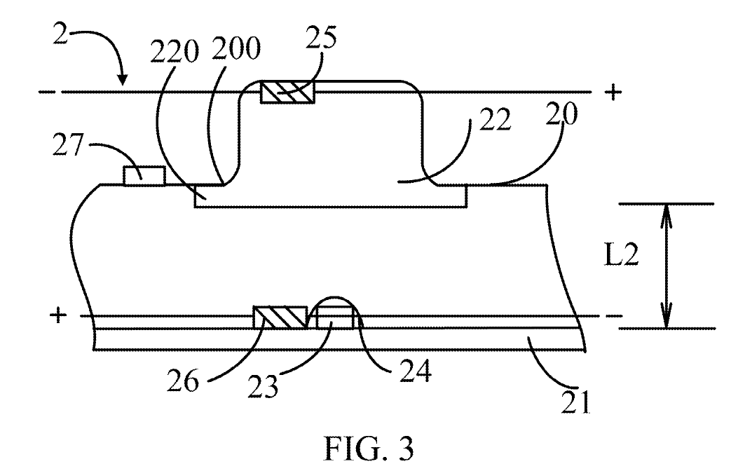

Referring to FIGS. 2-3, an exemplary embodiment of a keyboard 2 is illustrated. The keyboard 2 can be used in various electronic devices (not shown), such as personal digital assistants, mobile phones, and computers. The keyboard 2 includes a casing 20, a circuit board 21, and at least one button 22. FIGS. 2-3 only schematically show one button for the sake of simplicity. However, the number of the button 22 is not limited thereto and can be varied according to need.

The button 22 extends through a through hole 200 and is movably received in the casing 20. A portion of the button 22 protrudes from the top of the casing 20 via the through hole 200, allowing the button 22 to be operated by a user. In an exemplary embodiment, the button 22 includes a flange 220 extending around the periphery of a bottom of the button 22. The flange 220 is wider than the through hole 200 and can abut against the inner surface of the top of the casing 20 surrounding the through hole 200, which can prevent the button 22 from disengaging from the through hole 200. In an alternative embodiment, the button 22 may be movably connected to the casing 20 some other way known in the art, such as what has been used in cell phones.

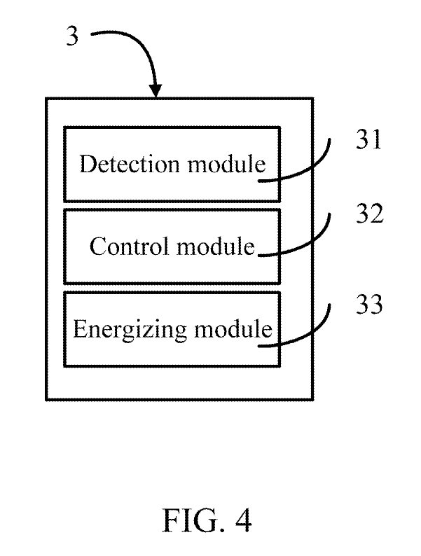

The circuit board 21 is located inside the casing 20 and includes a switch 23 under the button 22. When pushed, the button 22 moves and actuates the switch 23. The switch 23 then sends a signal to a processor 3 (shown in FIG. 4) of an electronic device. The processor 3 executes a corresponding operation in response to the received signal. An elastic element 24 is arranged between the switch 23 and the button 22 to return the button 22 to its original position when a user releases the button 22.

The keyboard 2 further includes a first electromagnet 25 and a second electromagnet 26. In an exemplary embodiment, the first electromagnet 25 is arranged inside the button 22, and the second electromagnet 26 is coupled to the circuit board 21 and corresponding to the first electromagnet 25. The first and second electromagnets 25, 26 are cylindrical in shape and located near the switch 23. In an alternative embodiment, the first and second electromagnets 25, 26 may be annular in shape. In such case, the switch 23 may be arranged within the second electromagnet 26. In yet another alternative embodiment, the first electromagnet 25 may be coupled to the bottom of the button 22. It is notable that the configuration and arrangement of the first and second electromagnets 25, 26 are not limited thereto and may be varied according to need provided that the first and second electromagnets 25, 26 are configured to repel each other when energized.

When the first and second electromagnets 25, 26 are not energized, the button 22 is kept in the original position shown in FIG. 2 by action of the elastic element 24 and the distance between the button 22 and the circuit board 21 equals L1. When energized, the first and second electromagnets 25, 26 repel each other and the first electromagnet 25 moves away from the circuit board 21, causing the distance between the button 22 and the circuit board 21 to become L2 as shown in FIG. 3 which is longer than L1. Once no longer energized, the first and second electromagnets 25, 26 stop repelling each other and the button 22 moves back to its original position under force of gravity or by other forces.

Energizing the first and second electromagnets 25, 26 is accomplished by either of two ways in the present embodiment. In one way, a power switch 27 is provided with the keyboard 2 as shown in FIGS. 2-3. The power switch 27 sends a signal to a processor 3 of the electronic device when it is pushed by a user. The processor 3 includes an energizing module 33 (shown in FIG. 4) for energizing the first and second electromagnets 25, 26 in response to the signal. Another way is discussed with reference to FIG. 4 below.

FIG. 4 is a block diagram of a processor 3 of the electronic device. The processor 3 includes a detection module 31, a control module 32, and an energizing module 33. The detection module 31 is used for generating a first signal after detecting that a specific application, e.g., a game application, starts running. The control module 32 receives the first signal and sends a second signal to the energizing module 33. The energizing module 33 then energizes the first and second electromagnets 25, 26 in response to the second signal.

Although the present disclosure has been described in accordance with the embodiments shown, one of ordinary skill in the art will readily recognize that there could be variations to the embodiments and those variations would be within the spirit and scope of the present disclosure. Accordingly, many modifications may be made by one of ordinary skill in the art without departing from the spirit and scope of the appended claims.

What is claimed is:

1. A keyboard comprising:
a circuit board;
a switch connected to the circuit board;
a button to actuate the switch;
a first electromagnet coupled to the button; and
a second electromagnet coupled to the circuit board and corresponding to the first electromagnet, wherein when energized, the first and second electromagnets repel each other and the first electromagnet moves away from the circuit board, causing the distance between the button and the switch to become longer.

2. The keyboard as described in claim 1, wherein the first electromagnet is located inside the button.

3. The keyboard as described in claim 1, wherein the first electromagnet is coupled to a bottom of the button.

4. The keyboard as described in claim 1, wherein the first and second electromagnets are cylindrical in shape.

5. The keyboard as described in claim 1, wherein the first and second electromagnets are annular in shape, and the switch is received in the second electromagnet.

6. An electronic device comprising:
a processor; and
a keyboard comprising:
a circuit board;
at least one button;
at least one switch each connected to the circuit board, corresponding to one of the at least one button, and to be actuated by the corresponding button;
at least one first electromagnet each coupled to one of the at least one button; and
at least one second electromagnet each coupled to the circuit board and corresponding to one of the at least one first electromagnet, wherein when energized, each first and the corresponding second electromagnets repel each other and the at least one first electromagnet moves away from the circuit board, causing the distance between the corresponding button and the corresponding switch to become longer.

7. The electronic device as described in claim 6, wherein the processor comprises:
a detection module for detecting whether a specific application starts running;
a control module for generating a signal when the detection module detects that a specific application starts running; and
an energizing module for energizing the at least one first and second electromagnets in response to the signal.

8. The electronic device as described in claim 6, further comprising a power switch for sending a signal to the processor when the power switch is actuated, wherein the processor comprises an energizing module for energizing the at least one first and second electromagnets in response to the signal.
